(19) United States
(12) Patent Application Publication
(10) Pub. No.: US 2025/0226843 A1
(43) Pub. Date: Jul. 10, 2025

(54) ACOUSTIC MULTIPLEXER FILTER CIRCUIT

(71) Applicant: Qorvo US, Inc., Greensboro, NC (US)

(72) Inventor: Nadim Khlat, Cugnaux (FR)

(21) Appl. No.: 18/958,490

(22) Filed: Nov. 25, 2024

Related U.S. Application Data
(60) Provisional application No. 63/619,366, filed on Jan. 10, 2024.

(51) Int. Cl. H04B 1/00; H03H 9/56

(52) U.S. Cl. CPC H04B 1/0057; H03H 9/568

(57) ABSTRACT

An acoustic multiplexer filter circuit and a wireless device containing the acoustic multiplexer filter circuit are provided. The acoustic multiplexer filter circuit includes multiple acoustic filter circuits each coupled to a common node. Each of the acoustic filter circuits is configured to pass a signal between a respective one of multiple signal nodes and the common node in one or more operating frequencies within a respective one of multiple passbands. In embodiments disclosed herein, each of the acoustic filter circuits can be tuned to present a respective high impedance at the common node in any of the operating 10 frequencies within any other ones of the plurality of passbands. As a result, each of the acoustic filter circuits can cause the signal to be reflected from the common node in selected operating frequencies outside the acoustic filter circuit's own passband to thereby improve overall performance of the acoustic multiplex filter circuit.

### RELATED APPLICATIONS

This application claims the benefit of U.S. provisional patent application Ser. No. 63/619,366, filed on Jan. 10, 2024, the disclosure of which is hereby incorporated herein by reference in its entirety.

### FIELD OF THE DISCLOSURE

The technology of the disclosure relates generally to an acoustic multiplexer filter.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as Surface Acoustic Wave (SAW) resonators and Bulk Acoustic Wave (BAW) resonators, are used in many high-frequency communication applications. In particular, SAW resonators are often employed in filter networks that operate at frequencies up to 1.8 GHz, and BAW resonators are often employed in filter networks that operate at frequencies above 1.5 GHz. Such SAW and BAW-based filters have flat passbands, steep filter skirts, and squared shoulders at the upper and lower ends of the passbands and provide excellent rejection outside of the passbands. SAW and BAW-based filters also have a relatively low insertion loss, tend to decrease in size as the frequency of operation increases, and are relatively stable over wide temperature ranges.

As such, SAW and BAW-based filters are the filter of choice for many wireless devices. Most of these wireless devices support cellular, wireless fidelity (Wi-Fi), Bluetooth, and/or near field communications on the same wireless device and, as such, pose extremely challenging filtering demands. While these demands keep raising the complexity of wireless devices, there is a constant need to improve the performance of acoustic resonators and filters that are based thereon.

### SUMMARY

Aspects disclosed in the detailed description include an acoustic multiplexer filter circuit and a wireless device containing therein the acoustic multiplexer filter circuit. The acoustic multiplexer filter circuit includes multiple acoustic filter circuits each coupled to a common node (e.g., an antenna port). Each of the acoustic filter circuits is configured to pass a signal between a respective one of multiple signal nodes and the common node in one or more operating frequencies (e.g., transmit and receive frequencies) within a respective one of multiple passbands. In embodiments disclosed herein, each of the acoustic filter circuits can be tuned to present a respective high impedance at the common node in any of the operating frequencies within any other ones of the plurality of passbands. As a result, each of the acoustic filter circuits can cause the signal to be reflected from the common node in selected operating frequencies (e.g., blocker frequencies) outside the acoustic filter circuit's own passband to thereby improve overall performance of the acoustic multiplex filter circuit.

In one aspect, an acoustic multiplexer filter circuit is provided. The acoustic multiplexer filter circuit includes multiple signal nodes and a common node. The acoustic multiplexer filter circuit also includes multiple acoustic filter circuits. Each of the multiple acoustic filter circuits is coupled between a respective one of the multiple signal nodes and the common node. Each of the multiple acoustic filter circuits is configured to pass a signal between the respective one of the multiple signal nodes and the common node in one or more operating frequencies within a respective one of multiple passbands. Each of the multiple acoustic filter circuits is also configured to present a respective one of multiple high impedances at the common node in any of the one or more operating frequencies within any of the multiple passbands that are different from the respective one of the multiple passbands.

In another aspect, a wireless device is provided. The wireless device includes an acoustic multiplexer filter circuit. The acoustic multiplexer filter circuit includes multiple signal nodes and a common node. The acoustic multiplexer filter circuit also includes multiple acoustic filter circuits. Each of the multiple acoustic filter circuits is coupled between a respective one of the multiple signal nodes and the common node. Each of the multiple acoustic filter circuits is configured to pass a signal between the respective one of the multiple signal nodes and the common node in one or more operating frequencies within a respective one of multiple passbands. Each of the multiple acoustic filter circuits is also configured to present a respective one of multiple high impedances at the common node in any of the one or more operating frequencies within any of the multiple passbands that are different from the respective one of the multiple passbands.

In another aspect, a method for operating an acoustic multiplexer filter circuit is provided. The method includes coupling each of multiple acoustic filter circuits between a respective one of multiple signal nodes and a common node. The method also includes passing a signal between the respective one of the multiple signal nodes and the common node in one or more operating frequencies within a respective one of multiple passbands. The method also includes presenting a respective one of multiple high impedances at the common node in any of the one or more operating frequencies within any of the multiple passbands that are different from the respective one of the multiple passbands.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary acoustic multiplexer filter circuit wherein each of multiple acoustic filter circuits can be configured to present a respective high impedance at a common node in any operating frequency outside a passband of the respective acoustic filter circuit;

FIG. 2 is a schematic diagram illustrating respective passbands of the acoustic filter circuits in FIG. 1;

FIG. 3 is a schematic diagram providing an exemplary illustration as to how any of the acoustic filter circuits in FIG. 1 can be tuned to present the respective high impedance in selected operating frequencies outside the passband of the respective acoustic filter circuit;

FIG. 4 is a schematic diagram of an exemplary acoustic filter circuit wherein a variable inductance circuit can be tuned to cause the acoustic filter circuit to present the respective high impedance at the common node when the acoustic filter circuit is provided in the acoustic multiplexer filter circuit of FIG. 1 as any of the acoustic filter circuits;

FIG. 5A is a schematic diagram of the variable inductance circuit configured according to one embodiment of the present disclosure;

FIG. 5B is a schematic diagram of the variable inductance circuit configured according to another embodiment of the present disclosure;

FIG. 6 is a schematic diagram of an exemplary wireless device incorporating the acoustic multiplexer filter circuit of FIG. 1;

FIG. 7 is a schematic diagram of an exemplary user element wherein the acoustic multiplexer filter circuit of FIG. 1 and/or the wireless device of FIG. 6 can be provided; and

FIG. 8 is a flowchart of an exemplary process for operating the acoustic multiplexer filter circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an acoustic multiplexer filter circuit and a wireless device containing therein the acoustic multiplexer filter circuit. The acoustic multiplexer filter circuit includes multiple acoustic filter circuits each coupled to a common node (e.g., an antenna port). Each of the acoustic filter circuits is configured to pass a signal between a respective one of multiple signal nodes and the common node in one or more operating frequencies (e.g., transmit and receive frequencies) within a respective one of multiple passbands. In embodiments disclosed herein, each of the acoustic filter circuits can be tuned to present a respective high impedance at the common node in any of the operating frequencies within any other ones of the plurality of passbands. As a result, each of the acoustic filter circuits can cause the signal to be reflected from the common node in selected operating frequencies (e.g., blocker frequencies) outside the acoustic filter circuit's own passband to thereby improve overall performance of the acoustic multiplex filter circuit.

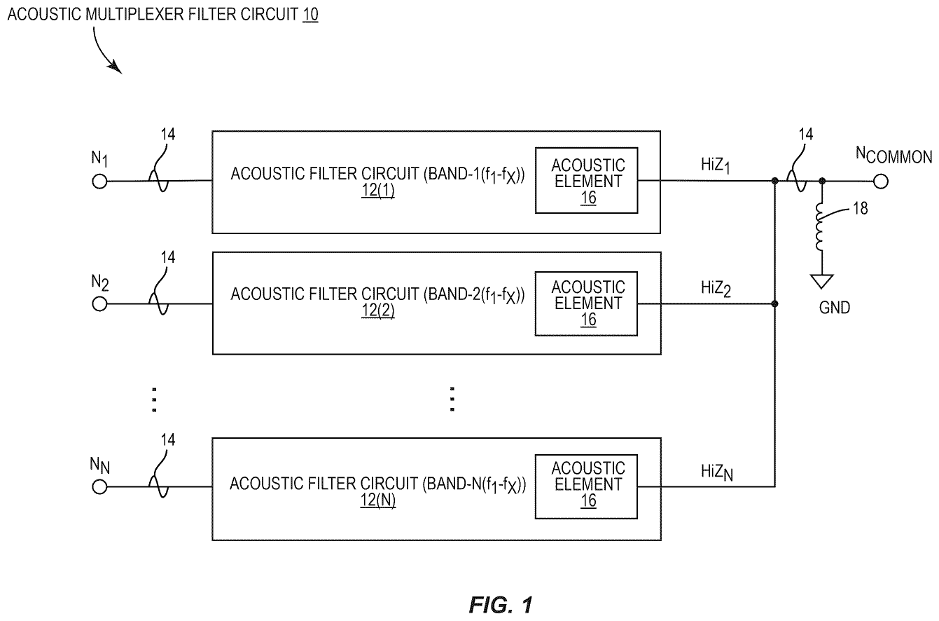

FIG. 1 is a schematic diagram of an exemplary acoustic multiplexer filter circuit 10 wherein each of multiple acoustic filter circuits 12(1)-12(N) can be configured to present a respective one of multiple high impedances HiZ₁-HiZ_{N} at a common node N_{COMMON} in any one or more of multiple operating frequencies f₁-fₓ of any one or more passbands Band-1-Band-N that is outside a respective passband Band-X ∈ (Band-1-Band-N) of the respective one of the acoustic filter circuits 12(1)-12(N). As an example, the acoustic filter circuit 12(1) will present the high impedance HiZ₁ at the common node N_{COMMON} in the passbands Band-2-Band-N, the acoustic filter circuit 12(2) will present the high impedance HiZ₂ at the common node N_{COMMON} in the passbands Band-1 and Band-3-Band-N, and so on.

Herein, the acoustic multiplexer filter circuit 10 includes multiple signal nodes N₁-N_{N} in addition to the common node N_{COMMON}. In a non-limiting example, the signal nodes N₁-N_{N} are coupled to a transceiver circuit (not shown) and the common node N_{COMMON} can be coupled to an antenna (not shown). Each of the acoustic filter circuits 12(1)-12(N) is coupled between a respective one of the signal nodes N₁-N_{N} and the common node N_{COMMON}. Each of the acoustic filter circuits 12(1)-12(N) is configured to pass a signal 14, which may be an outgoing signal to be transmitted via the antenna or an incoming signal received via the antenna, between the respective one of the signal nodes S₁-S_{N} and the common node N_{COMMON} in a respective one of the passbands Band-1-Band-N.

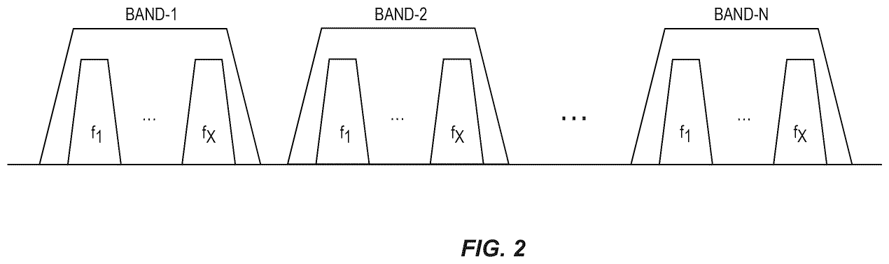

FIG. 2 is a schematic diagram illustrating the passbands Band-1-Band-N of the acoustic filter circuits 12(1)-12(N) in FIG. 1. Common elements between FIGS. 1 and 2 are shown therein with common element numbers and will not be re-described herein.

As shown in FIG. 2, each of the passbands Band-1-Band-N includes a respective one or more operating frequencies f₁-fₓ. Each of the operating frequencies f₁-fₓ has a narrower bandwidth than a respective one of the passbands Band-1-Band-N. In a non-limiting example, each of the operating frequencies f₁-fₓ can be utilized to simultaneously transmit and receive the signal 14 under such wireless communication schemes as frequency-division duplex (FDD) and a dual connectivity (DC).

In some cases, the passbands Band-1-Band-N may be close to one another. As a result, some of the operating frequencies f₁-fₓ in one of the passbands Band-1-Band-N may become blocker frequencies in another one (e.g., adjacent one) of the passbands Band-1-Band-N. Because the blocker frequencies can adversely impact performance of the acoustic multiplexer filter circuit 10, it is thus desirable to eliminate these blocker frequencies within each of the passbands Band-1-Band-N.

In this regard, with reference back to FIG. 1, each of the acoustic filter circuits 12(1)-12(N) is configured to include an acoustic element 16. As further discussed below, the acoustic element 16 in any one of the acoustic filter circuits 12(1)-12(N) can be tubed to cause the respective one of the acoustic filter circuits 12(1)-12(N) to present the respective one of the high impedances HiZ₁-HiZ_{N} at the common node N_{COMMON}. More specifically, the acoustic element 16 can cause any of the acoustic filter circuits 12(1)-12(N) to present the respective one of the high impedances HiZ₁-HiZ_{N} in one or more of the operating frequencies f₁-fₓ within any other ones of the passbands Band-1-Band-N.

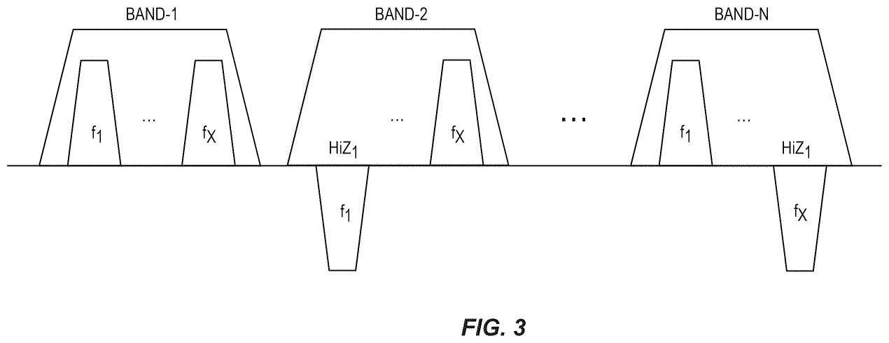

FIG. 3 is a schematic diagram illustrating one exemplary operating scenario of the acoustic multiplexer filter circuit 10 of FIG. 1. Common elements between FIGS. 1, 2, and 3 are shown therein with common element numbers and will not be re-described herein.

In this example, the acoustic element 16 in the acoustic filter circuit 12(1) is tuned to cause the acoustic filter circuit 12(1) to present the respective high impedance HiZ₁ at the common node N_{COMMON} in the operating frequency f₁ that falls within the adjacent passband Band-2 and in the operating frequency fₓ that falls within the non-adjacent passband Band-N. As a result, the signal 14 may be subject to a higher reflection at the common node N_{COMMON} in the operating frequency f₁ of the adjacent passband Band-2 and in the operating frequency fₓ of the non-adjacent passband Band-N. It should be appreciated that the acoustic element 16 in any of the acoustic filter circuits 12(1)-12(N) can be tuned to present the respective high impedances HiZ₁-HiZ_{N} in any of the operating frequencies f₁-fₓ within any other ones of the passbands Band-1-Band-N.

With reference back to FIG. 1, the acoustic multiplexer filter circuit 10 may further include a common inductor 18. In an embodiment, the common inductor 18 may be coupled between the common node N_{COMMON} and a ground (GND).

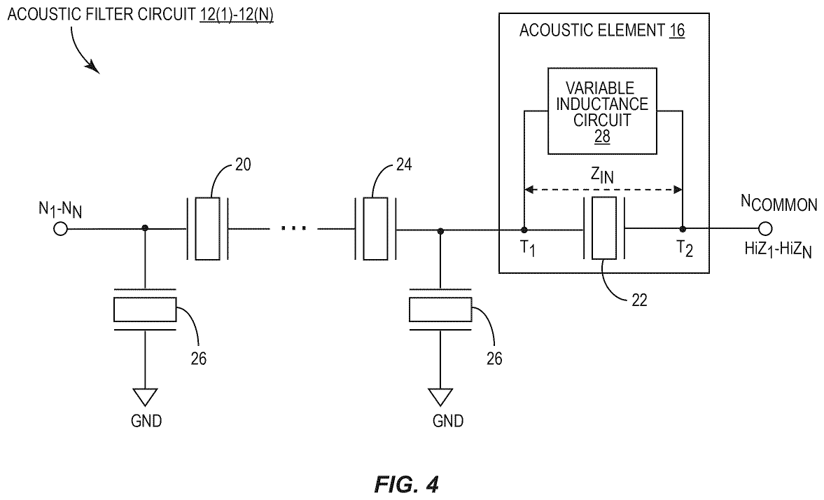

In an embodiment, each of the acoustic filter circuits 12(1)-12(N) can be an acoustic ladder network as illustrated in FIG. 4. FIG. 4 is a schematic diagram providing an exemplary illustration of each of the acoustic filter circuits 12(1)-12(N) in FIG. 1 configured according to an embodiment of the present disclosure. Common elements between FIGS. 1 and 4 are shown therein with common element numbers and will not be re-described herein.

Herein, each of the acoustic filter circuits 12(1)-12(N) includes an input series acoustic resonator 20 coupled to a respective one of the signal nodes N₁-N_{N}. Each of the acoustic filter circuits 12(1)-12(N) also includes an output series acoustic resonator 22 coupled to the common node N_{COMMON}. Each of the acoustic filter circuits 12(1)-12(N) may also include one or more intermediate series acoustic resonators 24 coupled between the input series acoustic resonator 20 and the output series acoustic resonator 22. Each of the acoustic filter circuits 12(1)-12(N) further includes one or more shunt acoustic resonators 26 coupled to the ground (GND).

According to an embodiment of the present disclosure, the acoustic element 16 includes the output series acoustic resonator 22 and a variable inductance circuit 28. Specifically, the variable inductance circuit 28 is coupled in parallel to the output series acoustic resonator 22. As illustrated herein, the variable inductance circuit 28 is coupled between an input T₁ and an output T₂ of the output series acoustic resonator 22. The variable inductance circuit 28 can be tuned to present a variable inductance Z_{IN} between the input T₁ and the output T₂ to thereby cause each of the acoustic filter circuits 12(1)-12(N) to present the respective high impedances HiZ₁-HiZ_{N} at the common node N_{COMMON}. For a more in-depth discussion of the operating theory and specific implementations of the variable inductance circuit 28, please refer to U.S. Provisional Patent Application No. 63/599,608, entitled “VARIABLE INDUCTANCE CIRCUIT.”

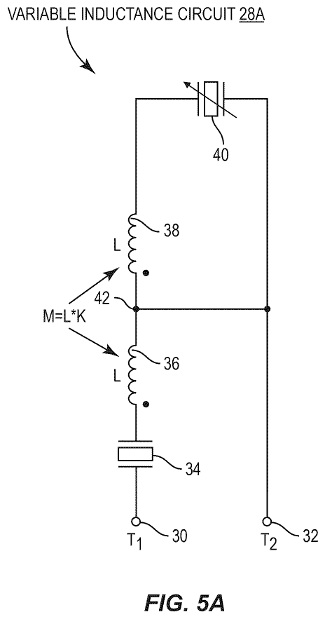

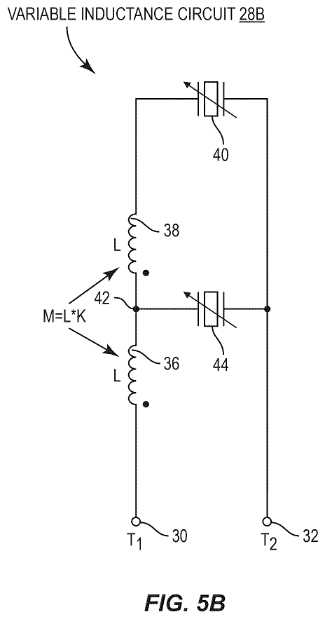

FIGS. 5A and 5B are schematic diagrams illustrating various implementations of the variable inductance circuit 28 in FIG. 4. Common elements between FIGS. 1, 4, and 5A-5B are shown therein with common element numbers and will not be re-described herein.

FIG. 5A illustrates a variable inductance circuit 28A configured according to one embodiment of the present disclosure. The variable inductance circuit 28A includes a first node 30 coupled to the input T₁ of the output series acoustic resonator 22 and a second node 32 coupled to the output T₂ of the output series acoustic resonator 22. The variable inductance circuit 28A also includes a first acoustic resonator 34, a pair of negatively coupled inductors 36, 38, and a tunable acoustic resonator 40 coupled in series between the first node 30 and the second node 32. In the variable inductance circuit 28A, a middle node 42, which is located in between the pair of negatively coupled inductors 36, 38, is coupled directly to the second node 32. Herein, each of the negatively coupled inductors 36, 38 has a respective inductance L and collectively provide a mutual inductance M (M=L*K), wherein K represents a coupling factor (0<K<1).

FIG. 5B illustrates a variable inductance circuit 28B configured according to another embodiment of the present disclosure. In addition to the negatively coupled inductors 36, 68 and the tunable acoustic resonator 40, the variable inductance circuit 28B includes a second tunable acoustic resonator 44 that is coupled between the middle node 42 the second node 32.

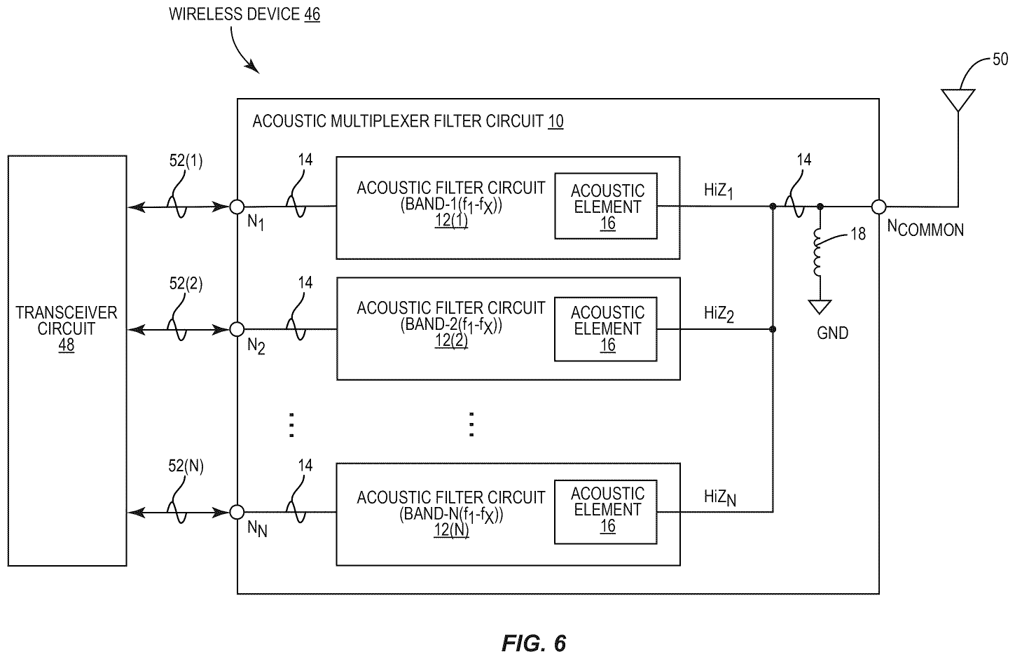

The acoustic multiplexer filter circuit 10 of FIG. 1 can be provided in a wireless device to enable various band filtering scenarios. In this regard, FIG. 6 is a schematic diagram of an exemplary wireless device 46 wherein the acoustic multiplexer filter circuit 10 of FIG. 1 can be provided. Common elements between FIGS. 1 and 6 are shown therein with common element numbers and will not be re-described herein.

In addition to the acoustic multiplexer filter circuit 10, the wireless device 46 can be configured to further include a transceiver circuit 48 and at least one antenna 50. The antenna 50 may be coupled to the common node N_{COMMON} and configured to radiate the signal 14 as an outgoing signal and/or absorb the signal 14 as an incoming signal. The transceiver circuit 48, on the other hand, may be coupled to each of the signal nodes N₁-N_{N} and configured to generate the signal 14 as the outgoing signal and/or receive the signal 14 as the incoming signal.

In an embodiment, the transceiver circuit 48 may be further configured to provide a respective one of multiple indications 52(1)-52(N) to a respective one of the acoustic filter circuits 12(1)-12(N). Each of the indications 52(1)-52(N) can cause the respective one of the acoustic filter circuits 12(1)-12(N) to present the respective one of the high impedances HiZ₁-HiZ_{N} at the common node N_{COMMON} in any of the operating frequencies f₁-fₓ within any of the passbands Band-1-Band-N.

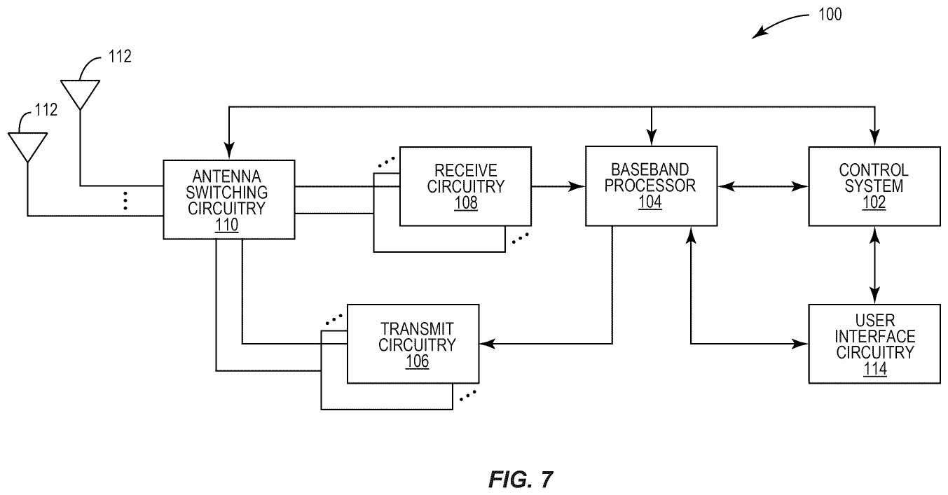

The acoustic multiplexer filter circuit 10 of FIG. 1 and/or the wireless device 46 of FIG. 6 incorporating the acoustic multiplexer filter circuit 10 of FIG. 1 can be provided in a user element to support the embodiments described above. In this regard, FIG. 7 is a schematic diagram of an exemplary user element 100 wherein the acoustic multiplexer filter circuit 10 of FIG. 1 and/or the wireless device 46 of FIG. 6 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

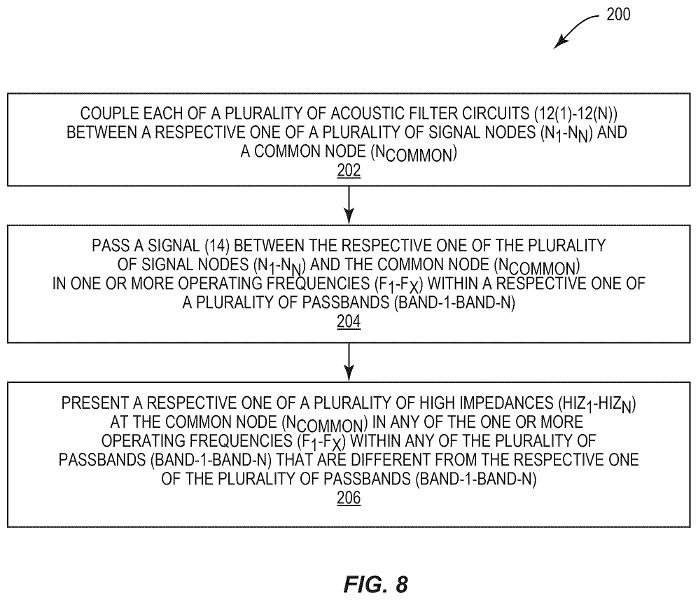

The acoustic multiplexer filter circuit 10 of FIG. 1 can be operated based on a process. In this regard, FIG. 8 is a flowchart of an exemplary process 200 for operating the acoustic multiplexer filter circuit 10 of FIG. 1.

Herein, the process 200 includes coupling each of the acoustic filter circuits 12(1)-12(N) between a respective one of the signal nodes N₁-N_{N} and the common node N_{COMMON} (step 202). The process 200 also includes passing the signal 14 between the respective one of the signal nodes N₁-N_{N} and the common node N_{COMMON} in one or more operating frequencies f₁-fₓ within a respective one of the passbands Band-1-Band-N (step 204). The process 200 also includes presenting a respective one of the high impedances HiZ₁-HiZ_{N} at the common node N_{COMMON} in any of the one or more operating frequencies f₁-fₓ within any of the passbands Band-1-Band-N that are different from the respective one of the passbands Band-1-Band-N (step 206).

Those skilled in the art will recognize improvements and modifications to the embodiments of the present disclosure. All such improvements and modifications are considered within the scope of the concepts disclosed herein and the claims that follow.

What is claimed is:

1. An acoustic multiplexer filter circuit comprising:
a plurality of signal nodes and a common node; and
a plurality of acoustic filter circuits each coupled between a respective one of the plurality of signal nodes and the common node and configured to:
pass a signal between the respective one of the plurality of signal nodes and the common node in one or more operating frequencies within a respective one of a plurality of passbands; and
present a respective one of a plurality of high impedances at the common node in any of the one or more operating frequencies within any of the plurality of passbands that are different from the respective one of the plurality of passbands.

2. The acoustic multiplexer filter circuit of claim 1, wherein each of the plurality of acoustic filter circuits comprises an acoustic element that is tunable to present the respective one of the plurality of high impedances at the common node in any of the one or more operating frequencies within any of the plurality of passbands that are different from the respective one of the plurality of passbands.

3. The acoustic multiplexer filter circuit of claim 2, wherein each of the plurality of acoustic filter circuits further comprises:
an input series acoustic resonator coupled to the respective one of the plurality of signal nodes;
an output series acoustic resonator coupled to the common node; and
one or more shunt acoustic resonators each coupled to a ground.

4. The acoustic multiplexer filter circuit of claim 3, wherein the acoustic element in each of the plurality of acoustic filter circuits comprises a variable inductance circuit coupled in parallel to the output series acoustic resonator in the respective one of the plurality of acoustic filter circuits.

5. The acoustic multiplexer filter circuit of claim 4, wherein the acoustic element in each of the plurality of acoustic filter circuits comprises:
a first node coupled to an input of the output series acoustic resonator;
a second node coupled to an output of the output series acoustic resonator;
a first acoustic resonator, a pair of negatively coupled inductors, and a tunable acoustic resonator coupled in series between the first node and the second node; and
a middle node located in between the pair of negatively coupled inductors coupled directly to the second node.

6. The acoustic multiplexer filter circuit of claim 4, wherein the acoustic element in each of the plurality of acoustic filter circuits comprises:
a first node coupled to an input of the output series acoustic resonator;
a second node coupled to an output of the output series acoustic resonator;
a pair of negatively coupled inductors, and a tunable acoustic resonator coupled in series between the first node and the second node; and
a second tunable acoustic resonator coupled between a middle node located in between the pair of negatively coupled inductors and the second node.

7. The acoustic multiplexer filter circuit of claim 1, further comprising a common inductor coupled between the common node and a ground.

8. A wireless device comprising an acoustic multiplexer filter circuit, comprising:
a plurality of signal nodes and a common node; and
a plurality of acoustic filter circuits each coupled between a respective one of the plurality of signal nodes and the common node and configured to:
pass a signal between the respective one of the plurality of signal nodes and the common node in one or more operating frequencies within a respective one of a plurality of passbands; and
present a respective one of a plurality of high impedances at the common node in any of the one or more operating frequencies within any of the plurality of passbands that are different from the respective one of the plurality of passbands.

9. The wireless device of claim 8, further comprising:
at least one antenna coupled to the common node and configured to radiate the signal as an outgoing signal and/or absorb the signal as an incoming signal; and
a transceiver circuit coupled to each of the plurality of signal nodes and configured to generate the outgoing signal and/or receive the incoming signal.

10. The wireless device of claim 9, wherein the transceiver circuit is further configured to provide a respective indication to each of the plurality of acoustic filter circuits to thereby cause each of the plurality of acoustic filter circuits to present the respective one of the plurality of high impedances at the common node in any of the one or more operating frequencies within any of the plurality of passbands that are different from the respective one of the plurality of passbands.

11. The wireless device of claim 9, wherein each of the plurality of acoustic filter circuits comprises an acoustic element that is tunable to present the respective one of the plurality of high impedances at the common node in any of the one or more operating frequencies within any of the plurality of passbands that are different from the respective one of the plurality of passbands.

12. The wireless device of claim 11, wherein each of the plurality of acoustic filter circuits further comprises:
an input series acoustic resonator coupled to the respective one of the plurality of signal nodes;
an output series acoustic resonator coupled to the common node; and
one or more shunt acoustic resonators each coupled to a ground.

13. The wireless device of claim 12, wherein the acoustic element in each of the plurality of acoustic filter circuits comprises a variable inductance circuit coupled in parallel to the output series acoustic resonator in the respective one of the plurality of acoustic filter circuits.

14. The wireless device of claim 13, wherein the acoustic element in each of the plurality of acoustic filter circuits comprises:
a first node coupled to an input of the output series acoustic resonator;
a second node coupled to an output of the output series acoustic resonator;
a first acoustic resonator, a pair of negatively coupled inductors, and a tunable acoustic resonator coupled in series between the first node and the second node; and
a middle node located in between the pair of negatively coupled inductors coupled directly to the second node.

15. The wireless device of claim 13, wherein the acoustic element in each of the plurality of acoustic filter circuits comprises:
a first node coupled to an input of the output series acoustic resonator;
a second node coupled to an output of the output series acoustic resonator;
a pair of negatively coupled inductors, and a tunable acoustic resonator coupled in series between the first node and the second node; and
a second tunable acoustic resonator coupled between a middle node located in between the pair of negatively coupled inductors and the second node.

16. The wireless device of claim 8, wherein the acoustic multiplexer filter circuit further comprises a common inductor coupled between the common node and a ground.

17. A method for operating an acoustic multiplexer filter circuit comprising:
coupling each of a plurality of acoustic filter circuits between a respective one of a plurality of signal nodes and a common node;
passing a signal between the respective one of the plurality of signal nodes and the common node in one or more operating frequencies within a respective one of a plurality of passbands; and
presenting a respective one of a plurality of high impedances at the common node in any of the one or more operating frequencies within any of the plurality of passbands that are different from the respective one of the plurality of passbands.

18. The method of claim 17, further comprising providing, in each of the plurality of acoustic filter circuits, an acoustic element that is tunable to present the respective one of the plurality of high impedances at the common node in any of the one or more operating frequencies within any of the plurality of passbands that are different from the respective one of the plurality of passbands.

19. The method of claim 18, further comprising providing, in each of the plurality of acoustic filter circuits:
an input series acoustic resonator coupled to the respective one of the plurality of signal nodes;
an output series acoustic resonator coupled to the common node; and
one or more shunt acoustic resonators each coupled to a ground.

20. The method of claim 19, further comprising providing, in the acoustic element in each of the plurality of acoustic filter circuits, a variable inductance circuit coupled in parallel to the output series acoustic resonator in the respective one of the plurality of acoustic filter circuits.
